(19) United States
(12) Patent Application Publication
(10) Pub. No.: US 2024/0401233 A1
(43) Pub. Date: Dec. 5, 2024

(54) PROCESS FOR PRODUCING A SINGLE CRYSTAL FROM SILICON

(71) Applicant: SILTRONIC AG, Munich (DE)

(72) Inventors: Walter HAECKL, Kirchweidach (DE); Gundars RATNIEKS, Burghausen (DE); Andreas SATTLER, Trostberg (DE); Maksims SUROVOVS, Riga (LV); Janis VIRBULIS, Pinki, Babites pag. (LV)

(21) Appl. No.: 18/688,812

(22) PCT Filed: Jul. 29, 2022
(86) PCT No.: PCT/EP2022/071394

§ 371 Date: Mar. 4, 2024

(30) Foreign Application Priority Data
Sep. 7, 2021 (EP) 21195228.8

(51) Int. Cl. C30B 29/06; C30B 15/24

(52) U.S. Cl. CPC C30B 29/06; C30B 15/24

(57) ABSTRACT

A process produces a single crystal of silicon. The process includes: installing a feed rod in a float-zone apparatus, having a diameter between 230-270 mm; installing a first hollow cylinder having an internal diameter larger, by 30-50 mm, than the feed rod's diameter; installing a second hollow cylinder having an internal diameter larger, by not 20-60 mm, than a crystal target diameter that is 290-310 mm; and pulling the single crystal of silicon. A pulling speed is 1.3-1.5 mm/min. A vertical distance of the bottom edge of the first hollow cylinder from the outer melting edge is smaller than 2 mm. The top edge of the second cylinder protrudes 1-10 mm over the crystallizing edge. A length of the single crystal is removed to form an ingot piece having a length 15-50 cm.

### CROSS REFERENCE TO RELATED APPLICATIONS

This application is a U.S. National Phase application under 35 U.S.C. § 371 of International Application No. PCT/EP2022/071394, filed on Jul. 29, 2022, and claims benefit to European Patent Application No. EP 21195228.8, filed on Sep. 7, 2021. The International Application was published in German on Mar. 16, 2023 as WO 2023/036514 A1 under PCT Article 21(2).

### FIELD

The present disclosure is directed to producing a monocrystalline ingot of silicon in a float-zone plant, and an ingot piece manufactured from it.

### BACKGROUND

The float-zone pulling of single crystals is known (see J. Bohm, et al.: “Handbook of Crystal Growth”, ed.: D. T. J. Hurle, vol. 2, Part A, 213-257, 1994) and is employed on the industrial scale for the production of monocrystalline materials. In this process, an induction coil containing a flow of high-frequency current is used to melt the starting material in the zone, this material then solidifying in the form of a single crystal as the material is pulled in the vertical direction, the resultant single crystal usually being rotated. Depending on the particular embodiment of the process, the single crystal may be pulled upward or downward. The electromagnetic field of the induction coil generates a flow in the molten zone that has a double vortex structure. This flow is directed continually inward in the middle of the zone, whereas, in the vicinity of the two ends of the melt zone, the flow is always directed radially outward. The resulting flow in the melt zone is generated not only by the electromagnetic forces but also by buoyancy and Marangoni forces and also by the rotation of ingot or crystal. The geometry of the solidifying phase boundary is established in accordance with the temperature distribution prevailing in the ingot, this distribution being influenced in turn by the flow conditions.

Flow control during float-zone pulling, and the associated improvements in crystal quality and operational stability, have been subjects of studies (see A. Mühlbauer, et al.: Journal of Crystal Growth, vol. 151, 66-79, 1995; S. Otani, et al.: Journal of Crystal Growth, vol. 66, 419-425, 1984; S. Y. Zhang, et al.: Journal of Crystal Growth, vol. 243, 410-418, 2002) which propose optimizing the operational parameters of induction coil geometry, induction coil current, ingot or crystal rotation, and pulling speed. Attempts have accordingly been made to homogenize the dopant distribution by varying the crystal rotation, by displacing the induction coil relative to the crystal axis, or by an optimized shape of the induction coil.

On the industrial scale, float-zone pulling is used in particular for the production of single crystals of silicon. A single crystal in this case is obtained from a polycrystalline feed rod, with the use of a monocrystalline silicon feed rod being another possible option.

For this process, the feed rod undergoes incipient melting at one end with the aid of a radiofrequency coil (inductor) and a monocrystalline seed crystal is attached to the resultant melt droplet. Material progressively melted from the feed rod serves as an ongoing supply for a single crystal subsequently growing on the seed crystal. A section of length referred to as the neck is crystallized first of all, in order to divert dislocations from the crystal lattice. The diameter of the growing single crystal is subsequently expanded to a target diameter in a section of length referred to as the initial cone (seed cone). After that, a section of length is produced in which the single crystal has the target diameter. At the end of the process, a section of length referred to as the end cone is also produced. The process may optionally also be concluded without an end cone, although in that case a part at the end of the section of length having the target diameter is unusable for the intended further processing because it exhibits dislocations.

The feed rod here is mounted with one end onto a rotatable shaft (pulling shaft) in such a way that it does not experience slip even if the direction of rotation changes abruptly. It is a requirement, moreover, that the middle of the other end of the feed rod is located at every point in time during crystal pulling on the axis of rotation of the pulling shaft. If the center of the other end were to move away from the axis of rotation of the pulling shaft, that would lead to considerable influencing of melting by the pulling coil, with the possible consequence of adverse influence on the entire pulling process.

The only monocrystalline silicon ingots presently available on the market are those having a diameter of nominally up to 200 mm, produced by the float-zone process.

The attainment of a larger target diameter than 200 mm in conjunction with maximized pulling speed has for a long time been a hitherto unfulfilled desire of the industry, as it promises greater returns (including, in particular, in the fabrication of components on the semiconductor wafers produced from the process).

The specification DE 101 37 856 A1 discloses a process of crucible-less float-zone pulling for producing a single silicon crystal which has a diameter of at least 200 mm over a length of at least 200 mm and in the region of this length is dislocation-free, there being a melt neck formed during float-zone pulling between a feed rod and the single crystal.

It nevertheless emerges that the pulling speed is too low for economically rational pulling of crystals.

Patent specification EP 2142686 A1 discloses a process for producing a single crystal by guiding a polycrystalline rod through a heating region in order to generate a molten zone, applying a magnetic field to the molten zone, and inducing the growth of a single crystal during solidification of the molten material on a single-crystal seed. The growing single crystal is placed in rotation in an alternately clockwise and counterclockwise pattern. The process is useful for the production of single silicon crystals having uniform electrical characteristics. Likewise disclosed is an apparatus for implementing the process. While the claims claim a crystal larger than 200 mm, no process is provided specifically for a diameter of 300 mm.

The specification US 2016 053 401 AA discloses an auxiliary heating device for a zone melting furnace and a heat preservation method for a single-crystal rod. The auxiliary heating device comprises an auxiliary heater disposed below a radiofrequency heating coil inside the zone melting furnace, this heater being formed by the winding of a hollow metallic circular pipe. The winding start end of the auxiliary heater is positioned on the upper part, the winding stop end of the auxiliary heating device is positioned on the lower part, and an upper end part and a lower end part are respectively guided out from the two ends; and a hollow cylindrical heating load is disposed on the inner side of the auxiliary heater, and an insulating part is disposed between the heating load and the auxiliary heater.

The specification DE 3 805 118 A1 discloses induction heating coils which are suitable for use for the pulling process without a crucible. Likewise shown are methods enabling optional adaptation of coils.

### SUMMARY

In an embodiment, the present disclosure provides a process that produces a single crystal of silicon. The process includes: installing a feed rod of silicon in a float-zone apparatus, the feed rod having a diameter of not less than 230 mm and not more than 270 mm; installing a first hollow cylinder having a bottom edge and an internal diameter, which is larger, by not less than 30 mm and not more than 50 mm, than the diameter of the feed rod; installing a second hollow cylinder having a top edge and an internal diameter, which is larger, by not less than 20 mm and not more than 60 mm, than a target diameter of the single crystal; and pulling a cylindrical part of the single crystal, which has the target diameter of not less than 290 mm and not more than 310 mm. The feed rod at a melting front forms an outer melting edge and a monocrystalline ingot on a growth side forms a crystallizing edge. A pulling speed is not less than 1.3 mm/min and not more than 1.5 mm/min. A vertical distance of the bottom edge of the first hollow cylinder from the outer melting edge is smaller than 2 mm. The top edge of the second cylinder protrudes not less than 1 mm and not more than 10 mm over the crystallizing edge. The process further includes removing a length of the single crystal to form an ingot piece having a length of not less than 15 cm and not more than 50 cm.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows an axial section through a float-zone plant during crystal pulling as needed for the process according to an aspect of the present disclosure; and

FIG. 2 shows the contour of a growth strip, determined as a function of the radius of the crystal and the length D of the crystal in the growth direction.

### DETAILED DESCRIPTION

Aspects of the present disclosure provide a process that allows a monocrystalline ingot to be produced by means of the Czochralski pulling process, where the axial variation of the dopant is minimal.

Aspects of the present disclosure likewise provide a corresponding crystal piece.

Aspects of the present disclosure provide advantages over the state of the art. For example, aspects according to the present disclosure solve the problem of cracking on single-crystal rods, which is caused by a disproportionate distribution of the thermal field and excessive thermal stresses in the growth process of zone-melted silicon single crystals above 6.5 inches.

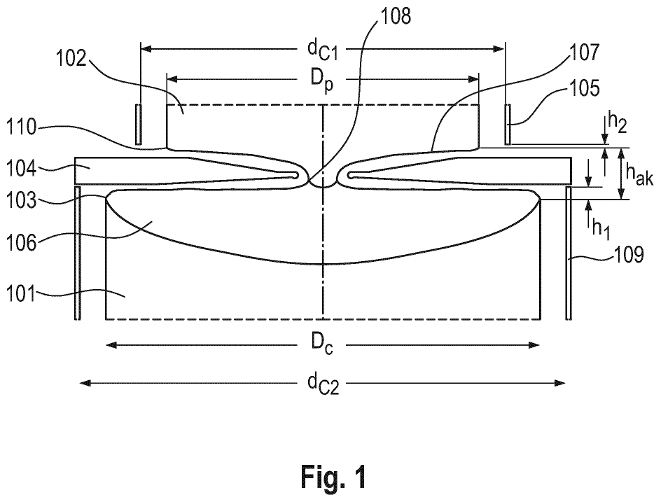

FIG. 1 shows an axial section through a float-zone plant during crystal pulling as needed for the process of the invention. Items shown include a feed rod (102) having a diameter Dₚ, a first hollow cylinder (105) having an inner diameter dc₁, a second hollow cylinder (109) having an inner diameter dc₂, a monocrystalline ingot (101), a melt (106), and a coil (104).

The parameter h₂ here defines the vertical distance of the top edge of the second hollow cylinder (109) from the crystallizing edge (103). The parameter h₁ here defines the vertical distance of the bottom edge of the first hollow cylinder (105) from the outer melting edge (110) of the feed rod. The vertical distance between the outer melting edge (110) and the crystallizing edge (103) is denoted by hₐₖ.

During crystal pulling the feed rod (102) is melted at the melting front (107). The point in the figure at which the feed rod, the melt, and the gas space coincide is called the internal triple point (108).

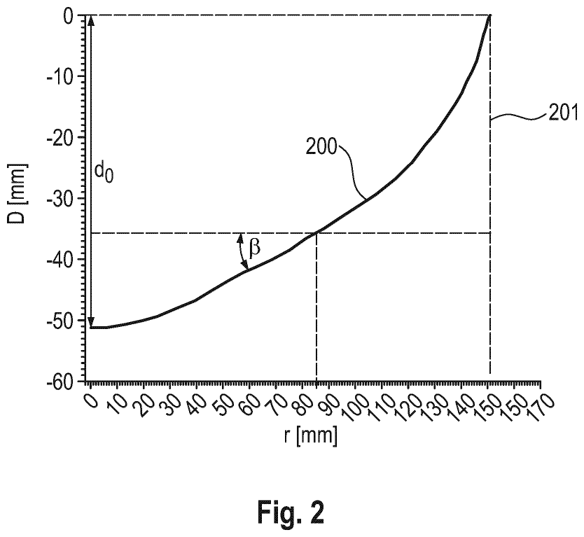

FIG. 2 shows the contour of a growth strip (201), determined as a function of the radius of the crystal and the length D of the crystal in the growth direction. The value d₀ here denotes the maximum deflection of the growth strip. A characteristic parameter for the process of the invention is the angle of incidence β, determined at the 85 mm radial position between a horizontal line and a tangent applied to growth strips.

Subject matter of the present disclosure includes a process for producing a single crystal of silicon by means of the float-zone process.

In order to achieve the object of maximum diameters in conjunction with high growth speeds, the inventors have recognized that a feed rod should be installed in the pulling plant that has a diameter of not less than 230 mm and not more than 270 mm.

Moreover, there should be a first hollow cylinder, installed beforehand, surrounding the feed rod when the crystal is being pulled. The internal diameter of the first hollow cylinder here should be larger by not less than 30 mm and not more than 50 mm than the diameter of the feed rod. Substantially here, the longitudinal axis of the first hollow cylinder and the longitudinal axis of the feed rod are to lie one above the other. Smaller radial deviations of less than 3 mm are sometimes unavoidable, but it is advantageous to minimize these deviations during installation.

Furthermore, a second hollow cylinder should be installed prior to crystal pulling in such a way that it surrounds the monocrystalline ingot that is subsequently pulled. The internal diameter of this second hollow cylinder should be larger by not less than 20 mm and not more than 60 mm than the target diameter of the monocrystalline ingot. Where, for example, a crystal having a target diameter of 300 mm is being pulled, it is preferred for the internal diameter to be between 320 mm and 360 mm.

The cylindrical part of the single crystal preferably has a diameter of not less than 290 mm and not more than 310 mm and a length which does not undershoot 15 cm. The maximum length of the cylindrical part of the ingot is dependent substantially on the dimensions of the crystal pulling plant.

For operational reasons, the diameter of a single crystal is subject to minor fluctuations which, while they can be minimized, cannot be eliminated entirely. The concept of the target diameter is therefore understood to refer to the average diameter of the single crystal.

As shown in FIG. 1, the feed rod forms an outer melting edge at the melting front, and the monocrystalline ingot forms a crystallizing edge on the growth side.

The inventors have recognized that during crystal pulling, the vertical distance of the bottom edge of the first hollow cylinder from the outer melting edge of the feed rod is preferably smaller than 2 mm. The bottom edge of the first hollow cylinder here is located above the outer melting edge of the feed rod. The first hollow cylinder is therefore shifted upward relative to the melting edge.

The length of the first hollow cylinder is more preferably at least 10 cm and is smaller than 50 cm. The material of which the first hollow cylinder is made consists preferably of silver, and very preferably, as a coating for the inner surface of the first hollow cylinder, a material is sought that has a high emissivity.

The emissivity of a body indicates how much radiation it emits in comparison to an ideal radiant heat emitter, a black body.

Gold, silver, silver alloys, carbon or copper and the like here are good candidates for carrying out a coating, with preference being given to the use of gold, silver, or silver alloys, as in these cases there is no risk of contamination of the melt or of the single crystal.

More preferably the first hollow cylinder may be composed of two hollow cylinders, in which case a lower hollow cylinder may preferably be provided with active heating. The active heating might preferably take the form of a device similar to that described in US 2016 053 401 AA.

The inventors placed particular attention on ensuring that the top edge of the second cylinder projects over the crystallizing edge. With particular preference here the vertical distance between crystallizing edge and top edge of the second hollow cylinder is not less than 1 mm and not more than 10 mm.

As for the first hollow cylinder, the material of which the second hollow cylinder is made should be selected such that the emissivity is as high as possible on the inside of the hollow cylinder. Preferably, in addition, the second hollow cylinder is composed of two hollow cylinders made from different materials.

The lower part of the second hollow cylinder, being the part at a greater distance from the coil, is preferably made of silver. Very preferably it comprises a surface treatment, such as a coating with silver or gold or alloys thereof on the inside, in order to maximize the emissivity.

The upper part of the second hollow cylinder, i.e., the hollow cylinder which faces the coil, is preferably made of a material which firstly has high emissivity on the inside and at the same time is robust with respect to high temperatures (i.e., larger than 1000° C.). Recommended candidates for this part include ceramic materials or else platinum or platinum-coated ceramics.

The second hollow cylinder preferably also has passages and holes which enable an image processing system to have a free view of the crystallizing edge of the single crystal. It should be ensured more particularly that these passages and holes are made as small as possible and as large as necessary, since they can adversely impact the pulling operation.

The pulling speed is preferably not less than 1.3 mm/min and not more than 1.5 mm/min, preferably not less than 1.35 mm/min and not more than 1.45 mm/min. The pulling speed is understood to be the speed at which the monocrystalline ingot grows in the axial direction. For a given pulling speed, the speed at which the feed rod must be supplied can be easily calculated by way of the corresponding mass balance.

The length of the second hollow cylinder is preferably more than 10 cm and not more than 40 cm.

The wall thickness of the two hollow cylinders is preferably not more than 10 mm and not less than 3 mm.

As is customary for the float-zone process, the gas space contains nitrogen, which enters into the crystal that is pulled.

Crystals pulled by the process just described may be further-processed like conventional crystals from the Czochralski pulling process.

The further-processing preferably comprises the following steps: the circular grinding of the single crystal, the removal of the lengths of the ingot to form ingot pieces, the sawing of an ingot piece into wafers, and the grinding and polishing of the wafers of the single crystal.

Semiconductor wafers fabricated from ingots made according to the process just described are outstandingly suitable for use for the fabrication of power components which have a very low defect count. Responsibility for this is borne of the fact that with this process there is substantial absence of the interstitial oxygen for forming oxygen precipitates in the crystal lattice. A nominal diameter of 300 mm and a high pulling speed make this operation highly economic and therefore hitherto unattained.

Following application of the process of the invention, a monocrystalline ingot is obtained which has a nominal diameter of not less than 290 mm and not more than 330 mm. This ingot is preferably cut into ingot pieces having a length of not less than 15 cm and not larger than 50 cm.

Where, for example, an ingot piece obtained in this way and having a diameter of 300 mm and a length of 20 cm is cut according to its length (i.e., axially), it is possible to obtain a so-called plank having a width of 300 mm and a length of 20 cm.

Measurements can be conducted on a plank that characterize both the crystal and the pulling process used for producing the crystal.

The dopant which is added usually in gas form to the melt during the float-zone process undergoes irregular incorporation into the crystal. This dopant preferably contains boron or phosphorus. This leads to a locally nonuniform resistance distribution of the silicon, which is called “striations”.

Although great efforts are made to avoid striations, in order not to suffer adverse effects during component operation, striations are nevertheless always measurable as soon as the pulled ingot has been doped in the float-zone process.

Because the dopant is incorporated from the melt into the crystal along the melt/crystal interface, the original form of the interface between crystal and melt can be ascertained in the form of growth strips by analyzing the measured resistance distribution. Reference may be made, illustratively, to two references devoted to this measurement and evaluation process:

Investigation of defects and striations in as-grown Si crystals by SEM using Schottky diodes, Appl. Phys. Lett. 27, 313 (1975); <<doi.org/10.1063/1.88482>>, A. J. R. de Kock, S. D. Ferris, L. C. Kimerling, and H. J. Leamy and Lüdge, A., Riemann, H.: Doping inhomogeneities in silicon crystals detected by the lateral photovoltage scanning (LPS) Method. Inst. Phys. Conf. Ser. 160, 145-148 (1997).

The latter source (Lüdge et al.) describes the method of “lateral photovoltage scanning” (LPS), which is also suitable for reconstructing the interface between crystal and melt, in other words the growth strips, when the resistance brought about by doping is high, and hence the dopant concentration is low.

If the method of “lateral photovoltage scanning” (LPS) is applied to the plank described above, it is possible to ascertain contours in the growth strips that precisely reproduce the deflection of the interface between melt and crystal.

A contour of a growth strip of a crystal (201) pulled by the disclosed process has been shown in FIG. 2.

It is possible to derive two characteristic variables that describe the properties of the crystal piece:
(1) the maximum deflection d₀ of the growth strips, and
(2) the angle of incidence β between a horizontal line and a tangent applied to growth strips, determined at the 85 mm radial position.

Preference is given to an ingot piece of silicon containing a dopant and having a diameter, an axial length of not less than 15 cm and not more than 50 cm, where the diameter is not less than 290 mm and not more than 330 mm and the ingot piece contains a radial extent of growth strips resulting from the dopant, where the maximum deflection of the growth strips is not less than 55 mm and not more than 45 mm.

It is particularly preferred if additionally an angle of incidence β is not smaller than 14° and not larger than 16°, where angle of incidence β is situated at the 80 mm radial position between a horizontal line and a tangent applied to the growth strips.

It is especially preferred if the ingot piece has an interstitial oxygen content of not more than 5×10¹⁵ at/cm³ (ASTM Standard F121-83) and an interstitial nitrogen content of not less than 1×10¹⁵ at/cm³ and not more than 7.5×10¹⁵ at/cm³.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### ABBREVIATIONS

101 monocrystalline ingot having a diameter D_{c}
102 silicon feed rod having a diameter Dₚ
103 crystallizing edge of the single crystal
104 coil
105 first hollow cylinder with an inner diameter dc₁
106 melt
107 melting front of the feed rod
108 internal triple point
109 second hollow cylinder with an inner diameter dc₂
110 outer melting edge of the feed rod
h₁ vertical distance of the bottom edge of the first hollow cylinder from the outer melting edge
h₂ vertical distance of the second cylinder from the crystallizing edge
hₐₖ vertical distance between the melting edge and the crystallizing edge
201 contour of a growth strip, determined as a function of the radius of the crystal and the length D of the crystal in the growth direction
202 cylindrical surface of the crystal
β angle of incidence determined at the 85 mm radial position between a horizontal line and a tangent applied to growth strips
d₀ maximum deflection of the growth strips

1: A process for producing a single crystal of silicon, the process comprising:
installing a feed rod of silicon in a float-zone apparatus, the feed rod having a diameter of not less than 230 mm and not more than 270 mm;
installing a first hollow cylinder having a bottom edge and an internal diameter, which is larger, by not less than 30 mm and not more than 50 mm, than the diameter of the feed rod;
installing a second hollow cylinder having a top edge and an internal diameter, which is larger, by not less than 20 mm and not more than 60 mm, than a target diameter of the single crystal;
pulling a cylindrical part of the single crystal, which has the target diameter of not less than 290 mm and not more than 310 mm, wherein
the feed rod at a melting front forms an outer melting edge and a monocrystalline ingot on a growth side forms a crystallizing edge,
a pulling speed is not less than 1.3 mm/min and not more than 1.5 mm/min,
a vertical distance of the bottom edge of the first hollow cylinder from the outer melting edge is smaller than 2 mm, and
the top edge of the second cylinder protrudes not less than 1 mm and not more than 10 mm over the crystallizing edge; and
removing a length of the single crystal to form an ingot piece having a length of not less than 15 cm and not more than 50 cm.

2: The process as claimed in claim 1, wherein:
the vertical distance between the melting edge and the crystallizing edge is not smaller than 35 mm and not larger than 40 mm.

3: The process as claimed in claim 1, wherein:
the feed rod has been produced by means of a Czochralski process.

4: The process as claimed in claim 1, wherein the process further comprises:
circularly grinding the single crystal;
sawing the ingot piece into wafers; and
grinding and polishing of the wafers.

5: An ingot piece of silicon, the ingot piece of silicon comprising a dopant and a single crystal, and having:
a diameter, and
an axial length of not less than 15 cm and not more than 50 cm,
wherein:
the diameter is not less than 290 mm and not more than 330 mm,
the single crystal contains a radial extent of growth strips governed by the dopant, and
a maximum deflection of the growth strips is not less than 55 mm and not more than 45 mm.

6: The ingot piece as claimed in claim 5, wherein:
there is an angle of incidence β between a horizontal line and a tangent applied to the growth strips, which at the 80 mm radial position is not smaller than 14° and not larger than 16°.

7: The ingot piece as claimed in claim 5, wherein:
the single crystal has an interstitial oxygen content of not more than 5×10¹⁵ at/cm³ (ASTM Standard F121-83).

8: The ingot piece as claimed in claim 5, wherein:
the single crystal has an interstitial nitrogen content of not less than 1×10¹⁵ at/cm³ and not more than 7.5×10¹⁵ at/cm³.
